(19) United States
(12) Patent Application Publication
(10) Pub. No.: US 2026/0209031 A1
(43) Pub. Date: Jul. 23, 2026

(54) MICROMECHANICAL PRESSURE SENSOR WITH ENCLOSED HOUSING WALL

(71) Applicant: Robert Bosch GmbH, Stuttgart (DE)

(72) Inventors: Jennifer Lai, Taipei City (TW); Alexander Littig, Reutlingen (DE); Daniel Haug, Neuffen (DE)

(21) Appl. No.: 19/449,740

(22) Filed: Jan. 15, 2026

(30) Foreign Application Priority Data
Jan. 21, 2025 (DE) 10 2025 102 059.0

(51) Int. Cl. B81B 7/00; B81C 1/00; G01L 19/14

(52) U.S. Cl. CPC B81B 7/0077; B81C 1/00333; G01L 19/147; B81B 2201/0264; B81B 2203/0127; B81C 2203/0136

(57) ABSTRACT

A micromechanical pressure sensor for detecting ambient pressure. The micromechanical pressure sensor includes a sensor element having a measurement variable that varies depending on the ambient pressure; a metal housing enclosing the sensor element at least along its edges by means of a housing wall; a first protective compound which is introduced within the metal housing and in which the sensor element is embedded in a manner protected from the environment; wherein the housing wall is coated on both sides with a second protective compound. A method for constructing a micromechanical pressure sensor is also described.

### CROSS REFERENCE

The present application claims the benefit under 35 U.S.C. § 119 of Germany Patent Application No. DE 10 2025 102 059.0 filed on January 21, 2025, which is expressly incorporated herein by reference in its entirety.

### FIELD

The present invention relates to a micromechanical pressure sensor. Furthermore, the present invention relates to a method for constructing a micromechanical pressure sensor.

### BACKGROUND INFORMATION

Germany Patent Application DE 102018222781 A1 describes a pressure sensor, comprising a support element and a sensor element attached thereto, which is surrounded by a housing that in turn is filled with a gel.

### SUMMARY

According to the present invention, a micromechanical pressure sensor for detecting ambient pressure is provided. According to an example embodiment of the present invention, the micromechanical pressure sensor includes: a sensor element having a measurement variable that varies depending on the ambient pressure; a metal housing enclosing the sensor element at least along its edges by means of a housing wall; a first protective compound which is introduced within the metal housing and in which the sensor element is embedded in a manner protected from the environment, wherein the housing wall is coated on both sides with a second protective compound.

As a result, the pressure sensor can be designed to be more robust against environmental influences and aging. The pressure sensor can be better protected against corrosion and environmental influences. The pressure sensor can be designed to be more cost-effective and robust.

The pressure sensor of the present invention can measure the fluid pressure of a fluid in the environment of the pressure sensor as ambient pressure. The fluid can be gaseous or liquid. The fluid can be air or water.

The pressure sensor of the present invention can be arranged in a mobile device, in particular a mobile electronic product, for example a smartphone, a vehicle or a stationary device, in particular for measuring water levels.

According to an example embodiment of the present invention, the sensor element can have a piezoresistive and/or capacitive measuring principle. The sensor element can comprise at least one membrane that can be deflected depending on the ambient pressure. The membrane can be covered by the first protective compound and protected from the environment. The ambient pressure can be transmitted to the sensor element via the first protective compound. The measurement variable can be an electrical capacitance and/or an electrical resistance.

According to an example embodiment of the present invention, the metal housing can be made of steel, in particular a rust-free steel, preferably stainless steel. The housing wall can have a greater height in a normal direction than the wall thickness. The metal housing can, in addition to the edge-side enclosure, also comprise a cover for protecting the sensor element. The cover can be designed as a single piece with or separate from the housing wall.

The housing wall can completely surround the sensor element. The housing wall can serve as mechanical protection for the sensor element from the environment and/or as a fill limiter for the first protective compound.

Protection from the environment can mean shielding and/or insulation with respect to environmental influences from the environment.

According to an example embodiment of the present invention, the first protective compound can be gel-like. The first protective compound can be a silicone gel or a fluorosilicone gel. The first and the second protective compound can be made of the same or different materials. The first protective compound can be a protective gel. The first and/or second protective compound can be PFAS-free. PFAS stands for per- and polyfluorinated alkyl substances.

The first protective compound can extend beyond the housing wall in the normal direction. The first protective compound can completely cover the sensor element to protect it from the environment.

According to an example embodiment of the present invention, the second protective compound can be an elastomer, in particular silicone. The second protective compound can be applied by injection molding. The second protective compound can act as a sealing element against a receiving housing, into which the pressure sensor can be inserted. The second protective compound can cover the housing wall to protect it from the environment.

The second protective compound can comprise at least one step in the normal direction above the housing wall. The step can form an overflow limit for the first protective compound, in particular during a casting process for filling in the first protective compound.

The sensor element can be arranged on a support element. The metal housing can be arranged on a support element. The sensor element and the metal housing can be arranged on a common support element. The metal housing can be glued onto a support element.

In a preferred embodiment of the present invention, it is advantageous if the metal housing comprises a base region on which the housing wall is arranged. The base region can extend around the sensor element. The base region can extend around the sensor element in a circular, polygonal or oval shape. The housing wall and the base region can be made from a single piece. The metal housing can be fastened to a support element via the base region. The base region and the support element can be glued together. The width of the base region can be greater than, equal to or less than the height of the base region in the normal direction.

The base region can have a base surface on which the housing wall is arranged. It can have the normal direction as its normal vector. The base surface can have a greater width perpendicular to the normal direction than the wall thickness of the housing wall. The housing wall can be arranged in the center of the base surface. The base surface can be arranged lower in the normal direction than a surface of the sensor element facing the environment. The sensor element can extend beyond the base region in the normal direction.

A preferred embodiment of the present invention is advantageous in which the housing wall is recessed relative to a base edge of the base region facing the sensor element. The housing wall can be recessed away from the sensor element. As a result, the metal housing can form a step. The step can be a transition from the base edge to the base surface. The base edge can be an inner surface of the base region facing the sensor element.

In an advantageous embodiment of the present invention, the second protective compound, extending along the housing wall, adjoins the base region. As a result, the second protective compound can be fastened more reliably to the housing wall. The second protective compound can extend in the normal direction from an upper side of the housing wall to the base region. The second protective compound can adjoin the base surface.

The second protective compound can adjoin the base region, forming at least one chamfer. The chamfer can be rounded. As a result, a nucleation point for the formation of bubbles in the first protective compound can be prevented.

In a particular example embodiment of the present invention, it is advantageous if the first protective compound at least partially adjoins the base region. The first protective compound can adjoin the base surface in sections. The first protective compound can cover the step as a transition between the base edge and the base surface.

In a specific example embodiment of the present invention, it is advantageous if the first and the second protective compound form an abutting surface with one another. The first and the second protective compound can directly adjoin one another via the abutting surface. The first and the second protective compound can be adhesively bonded to one another via the abutting surface, in particular by adhesion or by an integral bond. The abutting surface can extend within the interior region defined by the housing wall. The abutting surface can extend mainly in a straight line in the normal direction.

In a preferred example embodiment of the present invention, it is advantageous if the abutting surface extends from the base region, in a manner offset from the housing wall, in a normal direction toward the environment. The abutting surface can extend parallel to the housing wall in the normal direction.

In a preferred embodiment of the present invention, it is advantageous if the second protective compound completely encloses the housing wall. The second protective compound can cover an inner surface facing the sensor element and an outer surface facing the environment. The protective compound can completely cover an upper side of the housing wall. An average material thickness of the second protective compound on the inner surface can be less than, equal to, or greater than an average material thickness of the second protective compound on the outer surface. An average material thickness of the second protective compound on the inner surface and/or on the outer surface can be less than, equal to, or greater than a wall thickness of the housing wall.

A preferred embodiment of the present invention is advantageous in which the first protective compound is spaced apart from the housing wall. The abutting surface can overlap laterally with the base region. The abutting surface can extend laterally between the base edge and the housing wall in the normal direction.

According to the present invention, a method for constructing a micromechanical pressure sensor according to the present invention is also provided. According to an example embodiment of the present invention, the second protective compound can be applied to the housing wall by injection molding.

Further advantages and advantageous example embodiments of the present invention can be found in the description of the figures and in the figures.

### BRIEF DESCRIPTION OF THE DRAWINGS

The present invention is described in detail below with reference to the figures.

FIG. 1 shows a cross-section of a micromechanical pressure sensor in a specific embodiment of the present invention.

FIG. 2 shows a cross-section of a micromechanical pressure sensor in a further specific embodiment of the present invention.

FIGS. 3A and 3B show a method for constructing a micromechanical pressure sensor in a further specific embodiment of the present invention.

### DETAILED DESCRIPTION OF EXAMPLE EMBODIMENTS

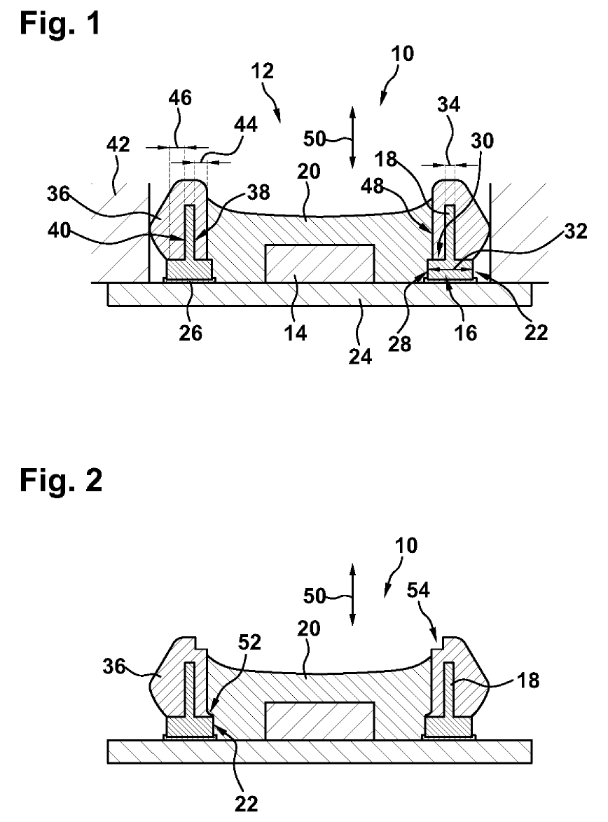

FIG. 1 shows a cross-section of a micromechanical pressure sensor in a specific embodiment of the present invention. The micromechanical pressure sensor 10 is designed to detect ambient pressure in an environment 12 of the pressure sensor, for example as an absolute pressure sensor, and comprises a sensor element 14 that has a measurement variable that varies depending on the ambient pressure, a metal housing 16 that encloses the sensor element 14 at least along its edges and has a housing wall 18 facing the environment 12, and a first protective compound 20 which is introduced within the metal housing 16 and in which the sensor element 14 is embedded in a manner protected from the environment 12. The first protective compound 20 is in particular a protective gel.

The sensor element 14 can have a measurement variable that varies depending on the ambient pressure. For example, the sensor element 14 can comprise a piezoresistive and/or capacitive measuring principle. The sensor element 14 is protected from the environment 12 by the first protective compound 20. The first protective compound 20 completely covers the sensor element 14. The ambient pressure can be transmitted to the sensor element 14 via the first protective compound 20.

The metal housing 16 comprises a base region 22, on which the housing wall 18 is arranged. The base region 22 and the housing wall 18 are in particular made from a single piece. The base region 22 and the sensor element 14 are arranged on a common support element 24. The base region 22 can be connected to the support element 24 by an adhesive layer 26.

The base region 22 comprises a base edge 28 facing the sensor element 14. The housing wall 18 is recessed away from the base edge 28 and the sensor element 14. The housing wall 18 extends from a base surface 30 of the base region 22, which has a greater width 32 than a wall thickness 34 of the housing wall 18. The housing wall 18 can be arranged centrally on the base surface 30.

The housing wall 18 is coated on both sides with a second protective compound 36 for protection from the environment 12.

As a result, the second housing wall 18 of the metal housing 16 is protected from corrosion. The second protective compound 36 is, for example, silicone, which completely encloses the housing wall 18. The second protective compound 36 covers in particular an inner surface 38 facing the sensor element 14 and an outer surface 40 facing the environment 12. The second protective compound 36 attached to the outer surface 40 can act as a sealing element against a receiving housing 42, into which the pressure sensor can be inserted.

The second protective compound 36 extends to the base region 22 and adjoins the base surface 30. An average material thickness 44 of the second protective compound 36 on the inner surface 38 is smaller than an average material thickness 46 of the second protective compound 36 on the outer surface 40. For example, an average material thickness 44 of the second protective compound 36 on the inner surface 38 is greater than the wall thickness 34 of the housing wall 18.

The first protective compound 20 adjoins the base edge 28 and also partially the base surface 30. The first and the second protective compound 20, 36 form an abutting surface 48 with one another, which extends from the base region 22, in a manner offset from the housing wall 18, in a normal direction 50 toward the environment 12.

FIG. 2 shows a cross-section of a micromechanical pressure sensor in a further specific embodiment of the present invention. The micromechanical pressure sensor 10 is constructed as shown in FIG. 1 with the following differences. The second protective compound 36 is connected to the base region 22 by forming a rounded chamfer 52. As a result, a nucleation point for the formation of bubbles in the first protective compound 20 can be prevented.

Furthermore, the second protective compound 36 comprises a step 54 in the normal direction 50 above the housing wall 18, which serves as an overflow limit for the first protective compound 20.

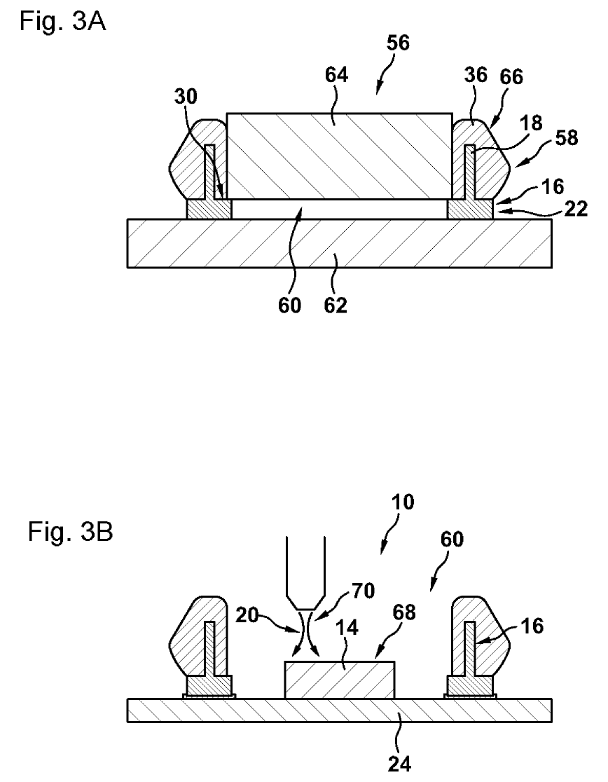

FIGS. 3A and 3B show a method for constructing a micromechanical pressure sensor in a further specific embodiment of the present invention. The method for constructing 56 a micromechanical pressure sensor 10, as shown in FIG. 3A, initially comprises providing 58 a metal housing 16 having a housing wall 18 delimiting an interior region 60, which housing wall adjoins a base region 22 made from a single piece. The metal housing 16 is received on a casting support 62. A mold insert 64 is inserted into the metal housing 16, which insert rests in particular on the base surface 30 of the base region 22.

Subsequently, the housing wall 18 is enclosed 66 with the second protective compound 36, for example by injection molding. The mold insert 64 and the base surface 30 serve as a boundary for the second protective compound 36 during the casting process.

Subsequently, as shown in FIG. 3B, the sensor element 14 is arranged 68 in the interior region 60. The sensor element 14 and the metal housing 16 are both fastened to the common support element 24.

Subsequently, the sensor element 14 is embedded 70 by filling a first protective compound 20 inside the metal housing 16. As a result, the micromechanical pressure sensor 10 can be constructed as shown in FIG. 1.

What is claimed is:

1. A micromechanical pressure sensor for detecting ambient pressure, comprising:
a sensor element having a measurement variable that varies depending on the ambient pressure;
a metal housing enclosing the sensor element at least along edges of the sensor element by a housing wall of the metal housing; and
a first protective compound which is introduced within the metal housing and in which the sensor element is embedded in a manner protected from an environment;
wherein the housing wall is coated on both sides with a second protective compound.

2. The micromechanical pressure sensor according to claim 1, wherein the metal housing includes a base region on which the housing wall is arranged.

3. The micromechanical pressure sensor according to claim 2, wherein the housing wall is recessed relative to a base edge of the base region facing the sensor element.

4. The micromechanical pressure sensor according to claim 2, wherein the second protective compound, extending along the housing wall, adjoins the base region.

5. The micromechanical pressure sensor according to claim 2, wherein the first protective compound at least partially adjoins the base region.

6. The micromechanical pressure sensor according to claim 1, wherein the first protective compound and the second protective compound form an abutting surface with one another.

7. The micromechanical pressure sensor according to claim 2, wherein the first protective compound and the second protective compound form an abutting surface with one another, and wherein the abutting surface extends from the base region, in a manner offset from the housing wall, in a normal direction toward the environment.

8. The micromechanical pressure sensor according to claim 1, wherein the second protective compound completely encloses the housing wall.

9. The micromechanical pressure sensor according to claim 1, wherein the first protective compound is spaced apart from the housing wall.

10. A method for constructing a micromechanical pressure sensor for detecting ambient pressure in an environment, the method comprising the following steps:
providing a metal housing having a housing wall delimiting an interior region;
enclosing the housing wall with a second protective compound;
arranging a sensor element having a measurement variable dependent on the ambient pressure in the interior region; and
embedding the sensor element to protect the sensor element from the environment by filling a first protective compound inside the metal housing.
